(19) United States
(12) Patent Application Publication
(10) Pub. No.: US 2022/0197014 A1
(43) Pub. Date: Jun. 23, 2022

(54) ELECTROMECHANICAL MICROSYSTEM

(71) Applicant: COMMISSARIAT A L'ENERGIE ATOMIQUE ET AUX ENERGIES ALTERNATIVES, Paris (FR)

(72) Inventors: Laurent MOLLARD, Grenoble Cedex 09 (FR); Stéphane NICOLAS, Grenoble Cedex 09 (FR); Damien SAINT-PATRICE, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 17/558,143

(22) Filed: Dec. 21, 2021

(30) Foreign Application Priority Data
Dec. 21, 2020 (FR) 20 13826

(51) Int. Cl. G02B 26/08; G01L 9/00; B81B 3/00

(52) U.S. Cl. CPC G02B 26/0833; G01L 9/0041; B81B 2203/0127; B81B 2201/042; B81B 3/0045

(57) ABSTRACT

The invention relates to an electromechanical microsystem 1 including at least two electromechanical transducers 11 and 11a, a deformable diaphragm 12 and a cavity 13 hermetically containing a deformable medium 14 maintaining a constant volume under the action of an external pressure change. The deformable diaphragm forms a cavity wall and has at least one deformable free area 121. The electromechanical transducers are configured so that their movement is a function of the said external pressure change, and conversely, and be in the same direction for at least two of them. The electromechanical microsystem 1 is thus able to deform the free area of the diaphragm in step mode towards the inside or outside of the cavity.

### TECHNICAL FIELD

This invention relates to the field of electromechanical microsystems. A particularly advantageous application is the actuation or movement of objects, in particular over relatively large distances. The invention is also applicable to the field of contact detection. It can thus be used to make sensors.

### STATE OF THE ART

In various applications, there may be a need to move microscopic or even nanoscopic objects and/or a need to sense the movements of such objects. Microsystems are available that allow this.

When these microsystems are actuators, their performance is assessed in particular with respect to the following parameters: the amplitude of the movement, the force deployed and the precision of the movement generated. When these microsystems are sensors, their performance is assessed in particular with respect to the following parameters: the ability to sense a movement over a large amplitude and the measurement accuracy.

In addition, whether the microsystems are actuators or sensors, proper performance is sought in terms of size, energy consumption and ability to operate on a frequency basis.

All known solutions have poor performance for at least one of these parameters. In general, existing microsystems do not perform well enough for a combination of these parameters.

One of the purposes of this invention is to provide an electromechanical microsystem that has improved performance over existing solutions, at least for one of the above-mentioned parameters, or that provides a better compromise regarding at least two of the above-mentioned parameters.

It is a further purpose of this invention to provide an electromechanical microsystem that allows step-by-step movement, at least upward and downward, of an associated external member or that allows sensing of a movement, at least upward and downward, of an associated external member.

The other purposes, features and benefits of this invention will become apparent from the following description and accompanying drawings. It is understood that other benefits may be incorporated.

### Abstract

To achieve at least one of the above purposes, according to one embodiment, an electromechanical microsystem is provided comprising:
at least two electromechanical transducers each comprising at least a part moving between an equilibrium, non-loaded position and an out-of-equilibrium, loaded position,
a deformable diaphragm,
a deformable cavity delimited by walls.

At least one part of the deformable diaphragm forms at least one part of a first wall of the said cavity walls.

The cavity is configured to hermetically contain a deformable medium capable of maintaining a substantially-constant volume under the action of a change in external pressure exerted on the deformable medium through one of the cavity walls.

The moving part of each electromechanical transducer is configured so that its movement is a function of the said external pressure change or conversely that its movement causes an external pressure change. At least a part of the deformable diaphragm has at least an area free to deform, preferably elastically, in response to the said external pressure change.

The moving parts of the two electromechanical transducers are configured so that:
their loading or an increase in external pressure causes their movement towards the outside of the cavity, or
their loading or a decrease in external pressure causes their movement towards the inside of the cavity.

According to an optional embodiment, the electromechanical microsystem includes at least three electromechanical transducers each comprising a part moving between an equilibrium, non-loaded position and an out-of-equilibrium, loaded position:
the moving part of a first electromechanical transducer is configured so that its loading or an increase in external pressure causes its movement towards the outside of the cavity,
the moving part of a second electromechanical transducer is configured so that its loading or a decrease in external pressure causes its movement towards the inside of the cavity, and
the moving part of a third electromechanical transducer is configured so that its loading or an increase in external pressure causes its movement towards the outside and/or inside of the cavity.

According to one example, the free area is configured to cooperate with at least one external member so that its deformation causes, or is caused by, movement of the external member.

The proposed solution is thus able to move an external member in step mode, towards the inside or outside of the cavity, and/or to sense a movement of this member, towards the inside or outside of the cavity.

The loading of at least one, if not each, electromechanical transducer is such that its moving part moves from its equilibrium position to a given non-equilibrium position. A subsequent absence of load preferably returns the moving part of the transducer to its equilibrium position. Each transducer can thus have a binary behaviour. The microsystem thus allows step-by-step actuation, or motion sensing, of the external member, even when the behaviour of each transducer is binary. Such a microsystem operates advantageously with simplified electronics.

Each transducer may be loaded:
alternately to the other transducer or to several other transducers, or
in conjunction with one or more other transducers,
   in particular, so as to allow the free area of the diaphragm to achieve deformations different from those achieved by each transducer in isolation.

Alternatively or additionally, the proposed solution allows the electromechanical microsystem to sense:
a movement of the external member towards the inside of the cavity, and/or
a movement of the external member towards the outside of the cavity.

The electromechanical microsystem as introduced above is thus used to:
sense at least one movement of the external member, and/or
move the external member according to at least two movements which are different from each other, at least in their amplitude.

In the microsystem according to the said optional mode, the third transducer is used to:
either deform the free area of the diaphragm more than is possible by loading one the other two transducers,
or reduce the deformation of the free area of the diaphragm compared with what is possible by loading one or both of the other two transducers.

Whether the third transducer makes it possible to achieve an intermediate or increased deformation with respect to the deformations achieved by loading one or both the other transducers, it is understood that, through the microsystem according to the said optional mode, at least three different deformations of the free area of the diaphragm can be achieved gradually or by steps.

It should be further noted that the microsystem according to the said optional mode is thus advantageously less sensitive to a fault in one of the transducers, as the ones that remain functional continue to allow the external member to be moved upwards and/or downwards, or an upwards or downwards movement of the external member to be sensed.

The proposed solution also allows the electromechanical microsystem to form a so-called long-travel actuator, i.e. typically allowing the external member to move over a stroke length of at least 30 μm or even 100 μm (10⁻⁶ metre). Similarly, the proposed solution allows the electromechanical microsystem to form a so-called long-travel sensor, typically allowing a movement of at least 30 μm or even 100 μm (10⁻⁶ metre) to be sensed.

The electromechanical microsystem as introduced above is thus capable of moving the external member in step mode or of sensing a movement of this member, while presenting, in an easily modulable way, depending on the applications in question, a sufficient capability in terms of amplitude of movement and/or a sufficient capability in terms of deployed force and/or a capability in terms of sensing movement over an amplitude and/or with a sufficient accuracy and/or a capability to operate on a frequency basis and/or a size compatible with the applications in question, and/or a reduced energy consumption.

Another aspect of the invention relates to an opto-electromechanical system or microsystem including at least one electromechanical microsystem as introduced above and at least one optical microsystem.

Another aspect of the invention relates to a process of manufacturing an electromechanical microsystem as introduced above, comprising, or even being limited to, ordinary microelectronic deposition and etching steps. The electromechanical microsystem can in fact be manufactured by ordinary microelectronic means, which gives its manufacturer all the benefits of using these means, including a great deal of latitude in terms of sizing, adhesion energy between the different deposits, thickness of the various deposits, etching area, etc.

Based on an example, the process of manufacturing the electromechanical microsystem system includes the following steps:
a step involving the forming, on a substrate, of at least a portion of each of the said at least two electromechanical transducers, and then
a step involving the deposition of the deformable diaphragm, and then
a step involving the forming of an open cavity on the deformable diaphragm, and then
a step involving the filling with the deformable medium and the closing of the cavity, and
a step involving the etching the substrate to form a front face (FAV) of the electromechanical microsystem.

### BRIEF DESCRIPTION OF THE FIGURES

The purposes, aims and features and benefits of the invention will become clearer from the detailed description of one embodiment thereof which is shown by the following accompanying drawings in which:

FIG. 1A is a schematic diagram of a cross-sectional view or section of an electromechanical microsystem comprising three electromechanical transducers according to a first embodiment of the invention.

FIG. 1B is a schematic diagram of a top view of the electromechanical microsystem according to the first embodiment of the invention, with one of the three transducers being disc-shaped, and the two others each being ring-shaped, with one surrounding the first transducer and the other surrounding the free area of the diaphragm.

FIG. 1C is a schematic diagram of a cross-sectional view at the level of the transducers of a second embodiment of the invention.

FIG. 1D is a schematic diagram of a cross-sectional view at the level of the transducers of a third embodiment of the invention.

FIG. 1E is a schematic diagram of a cross-sectional view at the level of the transducers of a fourth embodiment of the invention.

FIG. 2 schematically represents a cross-sectional view or a section of an electromechanical microsystem according to the first embodiment of the invention.

FIG. 3A schematically represents a first embodiment of an opto-electromechanical microsystem comprising four electromechanical microsystems according to one embodiment of the invention.

FIG. 3B schematically represents a second embodiment of an opto-electromechanical microsystem comprising four electromechanical microsystems according to one embodiment of the invention.

FIGS. 4A and 4B each schematically represent other embodiments of an opto-electromechanical microsystem comprising four electromechanical microsystems according to one embodiment of the invention.

The drawings are given as examples and do not place any limit on the invention. They are schematic diagram representations intended to facilitate understanding of the invention and are not necessarily on the scale of practical applications. In particular, the thicknesses of the various layers, walls and members shown are not necessarily representative of reality. Also, the lateral dimensions of the piezoelectric elements, the free area of the diaphragm and/or the stops are not necessarily representative of reality, especially when considered in relation to each other.

### DETAILED DESCRIPTION

Before beginning a detailed review of embodiments of the invention, optional features are set forth below which may optionally be used in combination or alternatively.

According to one example, two of the said at least two electromechanical transducers extend, on at least one of the cavity walls, at a distance from the free area of the deformable diaphragm. In particular, they do not extend around the free area.

According to the above particular example, the first electromechanical transducer is shaped like a disc of radius R1 and the second electromechanical transducer is shaped like a ring extending in a radial extension R2 around the disc formed by the first electromechanical transducer. The sum of the radius R1 of the disc formed by the first electromechanical transducer and the radial extension R2 of the ring formed by the second electromechanical transducer is preferably less than 900 μm, or preferably less than 600 μm, or preferably less than 300 μm.

In addition to or as an alternative to the previous example, the radial extension R2 of the ring formed by the second electromechanical transducer is about twice as small as the radius R1 of the disc formed by the first electromechanical transducer.

According to the preceding example, with the microsystem comprising a third electromechanical transducer, and with the first and second electromechanical transducers contained within the boundaries of a circular area of given radius known as the “total radius” and noted Rₜₒₜ, with the said circular area comprising two parts, a first disc-shaped part centred on the said circular area and a second ring-shaped part extending around the first part, the said at least one first electromechanical transducer being contained more particularly within the first part of the circular area and the said at least one second electromechanical transducer being contained more particularly within the second part of the circular area. The first part of the circular area has a radius R_{2/3} substantially equal to two thirds of the total radius and the second part of the circular area has an extension E_{1/3} substantially equal to one third of the total radius. This ensures that, when the first and second electromechanical transducers include a PZT-based piezoelectric element, the first and second electromechanical transducers have opposing movements relative to each other.

In addition or as an alternative to the previous example, the second electromechanical transducer may be configured such that a movement of its moving part from its equilibrium position to its non-equilibrium position causes an increase in the external pressure acting on the deformable medium and the deformable diaphragm may be configured such that an increase in the external pressure acting on the deformable medium causes a deformation of the free area of the deformable diaphragm tending to move it away from the cavity (more specifically to move it away from a fixed cavity wall such as the wall opposite to the wall formed in part by the diaphragm). The electromechanical microsystem can thus be configured so as to cause a movement of the external member in a first direction, corresponding to a movement of the external member away from the cavity.

In addition to the previous feature, the first electromechanical transducer may be configured such that a movement of its moving part from its equilibrium position to its non-equilibrium position causes a deformation of the free area of the deformable diaphragm tending to move it towards the cavity (more specifically to move it towards a fixed cavity wall such as the wall opposite to the wall formed in part by the diaphragm). The electromechanical microsystem can thus be configured so as to cause a movement of the external member in a second direction, this second direction tending to move it towards the external member of the cavity (more specifically, move it towards a fixed cavity wall such as the wall opposite the wall formed in part by the diaphragm).

According to an example of the optional embodiment, the third electromechanical transducer extends over at least one of the walls of the cavity and over an annular area around the free area of the deformable diaphragm. The annular area over which the third electromechanical transducer extends may define the extension of the free area of the deformable diaphragm. The third electromechanical transducer may then be remote from the first and second electromechanical transducers and/or not be arranged around the first and second electromechanical transducers.

According to another example of the optional embodiment, the microsystem comprises, an alternative to or in addition to the third electromechanical transducer according to the previous example, at least one further ring-shaped electromechanical transducer and extending around the first disc-shaped electromechanical transducer or around the second ring-shaped electromechanical transducer. The moving part of the said at least one other electromechanical transducer, when the latter comprises a PZT-based piezoelectric element, is deformed under load, in opposite directions to each other, according to whether it is contained:
within a first part of a circular area within the boundaries of which the first and second electromechanical transducers and the said at least one other electromechanical transducer are contained, this first part having a radius R⅔ substantially equal to two thirds of the radius of the said circular area, or
within a second part of the circular area, this second part having an extension E⅓ substantially equal to one third of the radius of the circular area.

According to another example of the optional embodiment, the microsystem comprises, as an alternative to or in addition to the third electromechanical transducer and/or to the said at least one other electromechanical transducer, at least two other electromechanical transducers extending, on at least one of the walls of the cavity, at a distance from the free area of the deformable diaphragm and from the first and second electromechanical transducers and being arranged neither around the free area of the deformable diaphragm, nor around the first and second electromechanical transducers, a first of the said at least two other disc-shaped electromechanical transducers and a second of the said at least two other ring-shaped electromechanical transducers extending around the disc formed by the first of the said at least two other electromechanical transducers. The said at least two other electromechanical transducers may then have the same features as the first and second electromechanical transducers as introduced above.

According to one example, the deformable diaphragm has a plurality of free areas, which may differ in shape and/or size.

When the free area is configured to cooperate with at least one external member so that its deformation causes, or is caused by, a movement of the external member, the free area of the deformable diaphragm is configured to cooperate with the external member via a pin attached to the said free area, preferably in contact with the said free area, and more specifically in contact with an outer face of the free area.

According to the previous example, the pin may be attached in the centre of each free area of the deformable diaphragm. In this way, it is ensured that the movement of each pin is a translational movement perpendicular to the plane within which the cavity wall is contained, which is partly formed by the deformable diaphragm, when the diaphragm is not deformed.

Several pins may be provided.

Each pin may be configured to cooperate with the external member via a guide integral with the external member, so as to allow automatic positioning of the external member each the pin.

Each pin may be configured to be bonded to the external member by adhesion or magnetism, the energy with which the pin adheres to the free area of the deformable diaphragm preferably being greater than that with which the pin adheres to the external member. A connection, possibly removable, between each pin and the external member is thus provided which is largely adjustable in terms of holding force.

According to one example, each free area is free to deform, preferably elastically, in response to the said external pressure change.

The electromechanical microsystem as introduced above is preferably free of any optical element, such as a lens, in particular a variable focus lens.

At least a part of each electromechanical transducer forms a part of the cavity wall that is partially formed by the deformable diaphragm. The electromechanical microsystem according to this feature has a non-through structure, leaving the other walls of the cavity free so as to be able to carry out other functions thereon or so as to allow them to remain inert, for an increased integration capacity in particular in an opto-electromechanical microsystem.

Each electromechanical transducer can extend, directly or indirectly, over the deformable diaphragm.

According to one example, the moving part of at least one, or even of each, of the said at least two electromechanical transducers is integral with an area of the deformable diaphragm over which it extends, so that a movement of the said moving part causes a corresponding movement of the said area of the deformable diaphragm.

The deformable diaphragm is preferably configured so that its free area is capable of being deformed with an amplitude of at least 50 μm, or even of at least 100 μm, or even of at least 1000 μm, in a direction perpendicular to the plane in which it primarily extends when at rest. Without tearing and/or without significant wear, the electromechanical microsystem thus offers the ability to meet the requirements of many different applications requiring a large amount of travel, the latter being defined by the technical field concerned.

The moving part of at least one, or even each, of the said at least two electromechanical transducers may have a surface area at least twice as large as a surface area of the said free area of the deformable diaphragm. The surface area of the moving parts of the transducers is preferably at least 5 times or even 10 times or even 20 times larger than the surface area of the free area of the deformable diaphragm, or even than the surface area of the free areas of the deformable diaphragm.

The electromechanical microsystem may further comprise at least one lateral stop configured to guide the movement of an external member, when the free area is configured to cooperate with the said external member so that its deformation causes, or is caused by, a movement of the external member.

The said at least one lateral stop may be supported by the cavity wall that is partially formed by the deformable diaphragm. According to an optional example, the said lateral stop extends away from the cavity.

It is thus possible to:
limit, in a controlled, reliable and reproducible way, the tilt of the external member during the movement of the moving part of one of the electromechanical transducers, and/or
allow self-positioning of the external member relative to the free area of the deformable diaphragm, and/or
protect the deformable diaphragm, and more particularly its free area, in particular from any possibility of being torn off, when the external member is transferred or stuck.

According to one example, when the free area is configured to cooperate with an external member so that its deformation causes, or is caused by, a movement of the external member and that the free area of the deformable diaphragm is configured to cooperate with the external member via a pin attached to the said free area:

the pin may extend from the free area of the deformable diaphragm beyond the said at least one lateral stop or

the pin may extend from the free area of the deformable diaphragm within the at least one lateral stop.

The electromechanical microsystem according to either of the latter two alternatives provides satisfactory adaptability with a wide variety of external members and applications.

The electromechanical microsystem may further comprise at least one so-called bottom stop supported by the cavity wall opposite the free area of the deformable diaphragm, the said at least one bottom stop extending into the cavity towards the free area. It has a shape and dimensions configured to limit the deformation of the free area of the deformable diaphragm so as to protect the deformable diaphragm, and more particularly its free area, from any possibility of being torn off, in particular when the external member is transferred or stuck. Furthermore, the said at least one bottom stop may be shaped to limit the contact surface between the diaphragm and the cavity wall opposite the free area of the deformable diaphragm. This prevents the diaphragm from adhering to this wall.

At least one, and preferably each, of at least two electromechanical transducers may be a piezoelectric transducer, preferably comprising a PZT-based piezoelectric material.

If each electromechanical transducer is a piezoelectric transducer comprising a PZT-based piezoelectric transducer and the microsystem only includes two electromechanical transducers contained within the boundaries of a given circular area of given radius known as the “total radius” and noted Rₜₒₜ, with the said circular area comprising two parts, a first disc-shaped part centred on the said circular area and a second ring-shaped part extending around the first part, the first electromechanical transducer is preferably not contained entirely within the first part of the circular area, but extends beyond it, or the second electromechanical transducer is preferably not contained entirely within the second part of the circular area, but extends beyond it into the first part.

At least one, and preferably each, of the electromechanical transducers may be a statically-operating transducer. Alternatively or additionally, at least one, and preferably each, of the electromechanical transducers may be a vibratory-operating transducer with at least one resonant frequency, the said at least one resonant frequency being preferably less than 100 kHz, and even more preferably less than 1 kHz.

The deformable medium hermetically contained in the cavity may comprise at least one, preferably liquid, fluid. The fluid preferably has a viscosity of about 100 cSt (1 cSt=10-6 m2/s) at ambient temperature and pressure.

According to a non-limiting embodiment example, the fluid has a compressibility of between 10⁻⁹ and 10⁻¹⁰ Pa⁻¹ at 20° C., for example, of about 10⁻¹⁰ Pa⁻¹ at 20° C., without these values being limiting.

The electromechanical microsystem as introduced above may further include a plurality of deformable diaphragms and/or a plurality of free areas per deformable diaphragm.

The said at least one optical microsystem of the opto-electromechanical system as introduced above may include at least one, preferably silicon-based, mirror also referred to as a micromirror.

According to one example, the opto-electromechanical system is configured such that each movement of the moving part of at least one, preferably each, electromechanical transducer causes a movement of the at least one mirror.

Alternatively or additionally, the opto-electromechanical system may include a plurality of electromechanical microsystems each having at least a free area arranged opposite a part of the same optical microsystem, such as a mirror. Preferably, the electromechanical microsystem cooperates with the mirror in an area that is not in the centre of the mirror but, for example, in a corner of the mirror. This results in an opto-electromechanical system or microsystem with a large capacity to adapt its optical orientation.

The term “electromechanical microsystem” means a system including at least one mechanical element and at least one electromechanical transducer made on a micrometric scale by microelectronic means. The mechanical element can be set in motion (actuated) by a force generated by the electromechanical transducer. The latter can be powered by electrical voltages generated with nearby electronic circuits. Alternatively or additionally, the electromechanical transducer can sense a movement of the mechanical element; the electromechanical microsystem then acts as a sensor.

A “microsystem” is a system whose external dimensions are less than 1 centimetre (10⁻² metres) and preferably less than 1 millimetre (10⁻³ metres).

Most often, an electromechanical transducer acts as an interface between the mechanical and electrical domains. However, the term “electromechanical transducer” refers both to a piezoelectric transducer and a thermal transducer, the latter acting as an interface between the mechanical and thermal domains. An electromechanical transducer may comprise a part moving between an equilibrium, non-loaded position and an out-of-equilibrium, loaded position. When the transducer is piezoelectric, the loading is electrical. When the transducer is thermal, the loading is thermal.

When reference is made to the centre of the cavity, this centre is defined geometrically as the centre of a cavity with an undeformed free area of the deformable diaphragm.

“Below” and “above” mean “not greater than” and “not less than”, respectively. Equality is excluded by the use of the terms “strictly less than” and “strictly greater than ».

A parameter that is “substantially equal to/above/below” a given value means that the parameter is equal to/above/below the given value within plus or minus 20% or even 10% of that value. A parameter that is “substantially between” two given values means that the parameter is at least equal to the smaller given value within plus or minus 20% or 10% of that value and at most equal to the larger given value within plus or minus 20% or 10% of that value.

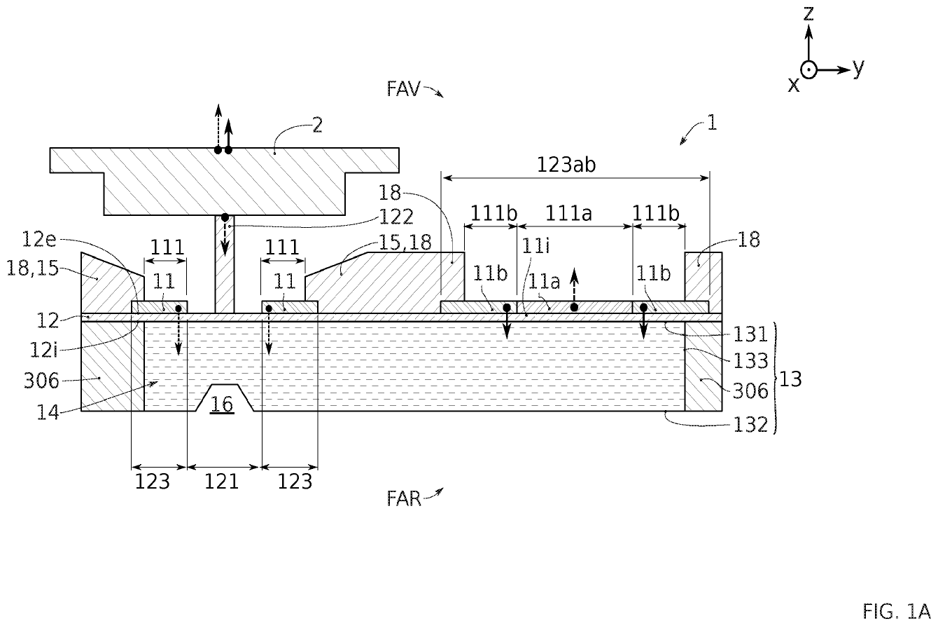

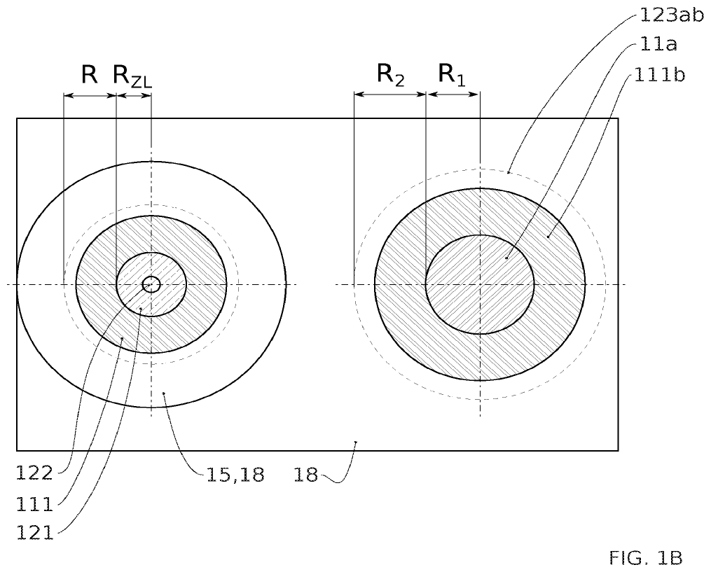

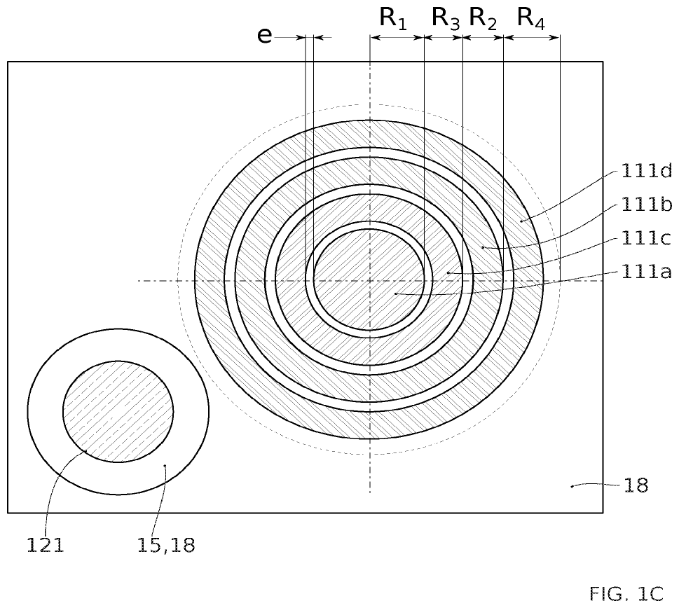

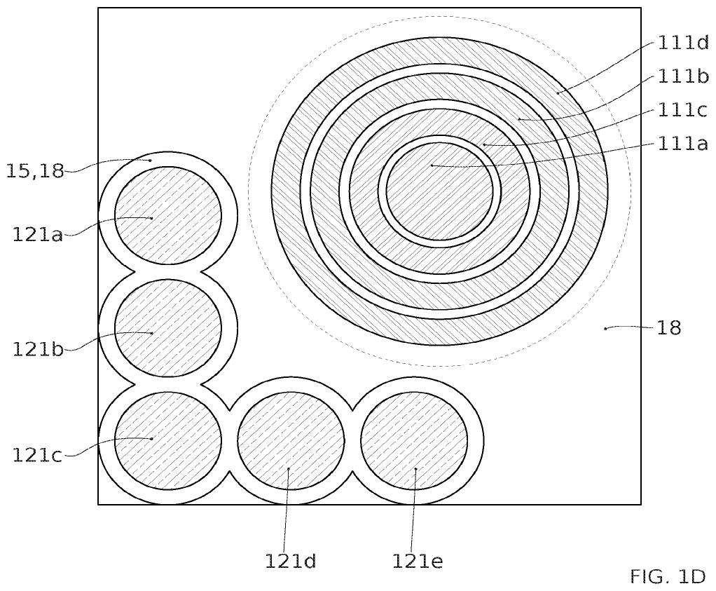

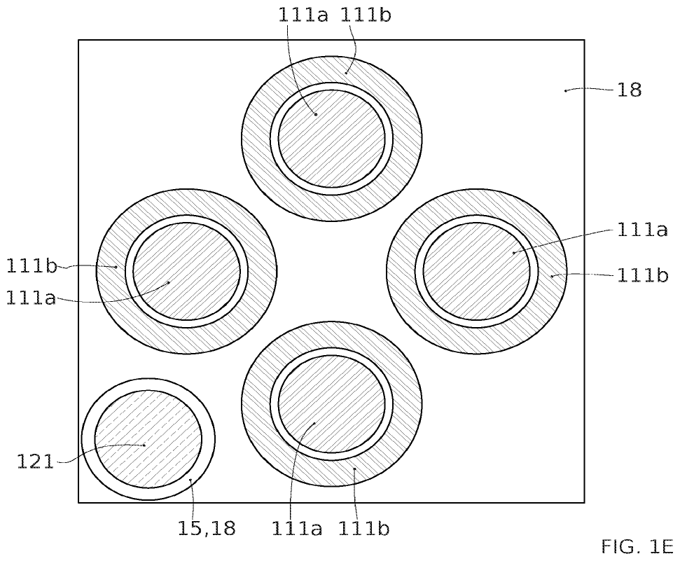

FIG. 1A is a schematic diagram of a cross-sectional view or section of an electromechanical microsystem 1 according to the first embodiment of the invention. FIG. 1A shows three electromechanical transducers 11, 11a and 11b, a deformable diaphragm 12 and a cavity 13 configured to hermetically contain a deformable medium 14.

This schematic diagram may represent a structure with no rotational or revolutionary symmetry about an axis perpendicular and centred with respect to the surface of the deformable diaphragm as shown, as well as a structure extending, for example, in a substantially invariant manner, perpendicularly to the shown cross-sectional view and symmetrical for a first part with respect to a plane perpendicular and centred with respect to the referenced area 121 and for a second part with respect to a plane perpendicular and centred with respect to the referenced area 111a.

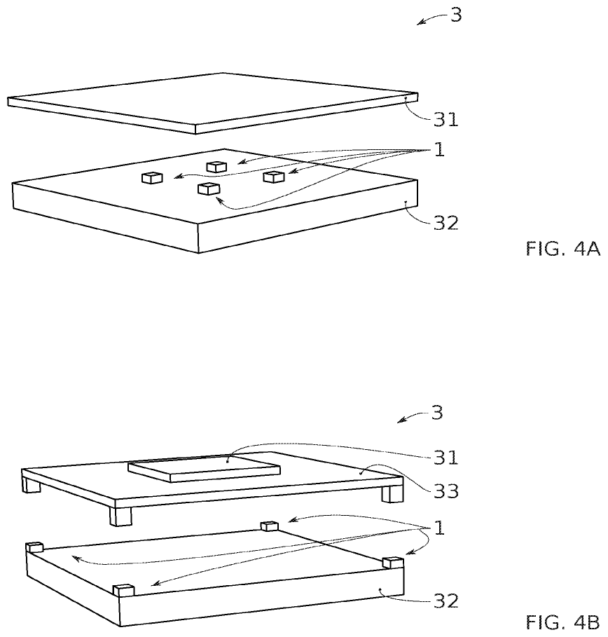

Before further describing the various embodiments of the invention shown in the appended figures, it should be further noted that each of these illustrations schematically represents an embodiment of the electromechanical microsystem according to the invention which has a non-through structure. More particularly, in the electromechanical transducers 11, 11a, 11b, 11c and 11d and the deformable diaphragm 12 are located on the front FAV of the electromechanical microsystem 1. This type of structure is particularly advantageous in that the rear FAR of the electromechanical microsystem 1 can participate only passively, and in particular without deforming, in the actuator and/or sensor function of the electromechanical microsystem 1. More particularly, the rear FAR of an electromechanical microsystem 1 with a non-through structure according to the invention may in particular form a face by which the electromechanical microsystem 1 may be easily fitted to a support (referenced 32 in FIGS. 4A and 4B) and/or may form a face by which the electromechanical microsystem may be easily further functionalised.

However, the invention is not limited to electromechanical microsystems with a non-through structure. In its broadest acceptance, the invention also relates to so-called through-structured microsystems 1 in which at least one of the transducers 11, 11a, 11b, 11c and 11d and the deformable diaphragm 12 are arranged on mutually distinct walls of the cavity 13, regardless of whether these walls are adjacent or opposite each other.

With reference to FIG. 1A, each electromechanical transducer 11, 11a, 11b comprises at least one moving part 111, 111a, 111b. The latter is configured to move or be moved between at least two positions. The first of these positions is an equilibrium position reached and maintained when the transducer 11, 11a, 11b is not loaded, either by an electrical voltage or by a force moving it away from its equilibrium position. The second of these positions of the moving part 111, 111a, 111b of the transducer 11, 11a, 11b is reached when the transducer is loaded, either, for example, by an electrical voltage or by a force moving it away from its equilibrium position. Each electromechanical transducer 11, 11a, 11b may be held in either of the first and second positions described above, and thus exhibit binary behaviour, or also be held in any intermediate position between its equilibrium position and its position of greatest deformation, or greatest deflection, from equilibrium. As will become clear from the following description of the invention, it is particularly advantageous for each electromechanical transducer 11, 11a, 11b to have a binary behaviour. This significantly simplifies the electronics, in particular allowing each transducer to be easily loaded independently or in conjunction with at least one other transducer.

In the example shown, when an electromechanical transducer 11, 11a, 11b is not loaded, its moving part 111, 111a, 111b extends primarily in a plane parallel to the plane xy of the orthogonal reference frame xyz shown in FIG. 1A.

At least one, and preferably each, electromechanical transducer 11, 11a, 11b is preferably a piezoelectric transducer. It is known that such a transducer converts an electrical power supply into a movement of its moving part 111, 111a, 111b from its equilibrium position to a non-equilibrium position and/or converts a movement of its moving part 111, 111a, 111b from its equilibrium position to a non-equilibrium position into an electrical signal. It is thus apparent from this example, but potentially remains true for each of the other contemplated embodiments of the electromechanical microsystem 1 according to the invention, that the latter can operate as an actuator and/or as a sensor. As an actuator, it may allow an external member 2 to be moved up and/or down, as shown in FIG. 1A. As a sensor, it may allow the sensing of a movement, in particular a vertical movement, of the external member 2, as also shown in FIG. 1A. To allow the generated signal to be a function of the movement of the external member 2, and in particular of its movement amplitude, it is preferable for the surface of the free area 121 to be larger than the surface of the moving parts 111, 111a, 111b of the electromechanical transducers 11, 11a, 11b which is in contact with the deformable diaphragm 12. In the following, for the sake of simplicity, the electromechanical microsystem 1 will be described essentially as an actuator, without, however, excluding its ability to provide alternatively or additionally, a sensor function.

At least one, if not each, electromechanical transducer 11, 11a, 11b is even more preferably a piezoelectric transducer comprising a PZT (Lead Titano-Zirconate) based piezoelectric material. In this case, the moving part 111, 111a, 111b of the transducer 11, 11a, 11b is able to move when subjected to a load with a more significant movement (due to the piezoelectric coefficient d31) than with many other piezoelectric materials. However, since PZT is a ferroelectric material, such piezoelectric transducers each preferentially operate in a single actuation direction (movement in a single direction of their moving part 111, 111a, 111b) regardless of the polarity of its power supply, whereas a piezoelectric transducer based on a non-ferroelectric material can preferentially operate in both directions (movement in two opposite directions of their moving part 111, 111a, 111b). Alternatively or additionally, at least one or each electromechanical transducer 11, 11a, 11b may be a piezoelectric (non-ferroelectric) transducer based on a material suitable for allowing its moving part 111, 111a, 111b to move in opposite directions relative to its equilibrium position depending on the polarity of its power supply. Such a material is, for example, an aluminium-nitride-based material (AlN).

Alternatively or additionally, at least one or each electromechanical transducer 11, 11a, 11b may be or include a thermal transducer.

The deformable diaphragm 12 may be polymer based, and is preferably PDMS (polydimethylsiloxane) based. The properties of the deformable diaphragm 12, in particular its thickness, surface area and shape, can be configured to provide the deformable diaphragm 12, and in particular an area 121 of the diaphragm that is free to deform, with an expected stretchability, in particular depending on the intended application.

The cavity 13 as shown in particular in FIG. 1A more particularly has walls 131, 132, 133 hermetically containing the deformable medium 14. In the examples shown, the wall 132 of the cavity 13 forms the rear FAR of the electromechanical microsystem 1. The wall 131 opposite the wall 132 is formed at least in part by at least a part of the deformable diaphragm 12. The wall 131 is thus deformable. The wall 131 is hereinafter referred to as the first wall. It is located on the front FAV of the electromechanical microsystem 1. At least one side wall 133 joins the walls 131 and 132 together. This side wall 133 may include or consist of at least one spacer 306 as shown in FIG. 1A, the role of which is detailed below. It will be noted that the sealing of the cavity 13 calls for the deformable diaphragm 12 to itself be impermeable, or rendered impermeable, in particular at its free area 121.

It should also be noted that, in order to more easily ensure the hermetic sealing of the cavity 13:
the first wall 131 of the cavity is preferably entirely formed or covered by at least the deformable diaphragm 12 and/or
each electromechanical transducer 11, 11a, 11b extends over the entire extension of the deformable diaphragm 12, being in direct or indirect contact therewith.

The walls 132, 133 preferably remain fixed as the diaphragm is deformed.

The deformable medium 14 is in turn capable of maintaining a substantially constant volume under the action of an external pressure change. In other words, it can be an incompressible or weakly compressible medium the deformation of which preferably requires little energy. For example, it is a liquid.

Since at least part of the wall 131 of the cavity 13 is formed by at least part of the deformable diaphragm 12, it is understood that any change in external pressure exerted on the deformable medium 14 can be compensated for by a substantially proportional deformation of the deformable diaphragm 12, and more particularly its free area 121, and/or by a movement of the moving part 111, 111a, 111b of one of the electromechanical transducers 11, 11a, 11b. When one of the transducers 11, 11a, 11b is loaded, this compensation is more particularly related to a conversion of the external pressure change exerted on the deformable medium 14 into a stretching of the deformable diaphragm 12. It is understood that, for the sake of reproducibility of the actuation or motion sensing offered by the electromechanical microsystem 1 according to the invention, it is preferable for any deformation of the deformable diaphragm 12 to be elastic, and not plastic, to ensure that the deformable diaphragm 12 returns to the same state of least stretch, or maximum relaxation, whenever it is no longer loaded.

The deformable medium 14 may more particularly include at least one, preferably liquid, fluid. The parameters of the liquid will be adjusted according to the intended applications. This ensures that any change in external pressure exerted on the deformable medium 14 causes a substantially proportional deformation of the free area 121 of the deformable diaphragm 12. The fluid may be a liquid or liquid based, such as oil, or may be a polymer or polymer based. According to one example, the fluid is based on or consists of glycerine. In this way, in addition to a substantially proportional deformation of the diaphragm 12, the deformable medium 14 is able to occupy, in particular, the volume created by stretching the free area 121 of the deformable diaphragm 12 opposite the centre of the cavity 13.

It is understood from the above that the electromechanical microsystem 1 is configured so that each movement of an electromechanical transducer 11, 11a, 11b depends on a change in the external pressure exerted on the deformable medium 14, in order to provide the actuator function of the electromechanical microsystem 1, and conversely, in order to provide the sensor function of the electromechanical microsystem 1. More particularly, when the electromechanical microsystem 1 acts as an actuator, at least one of the electromechanical transducers 11, 11a, 11b is loaded so as to exert an external pressure change on the deformable medium 14 and thereby cause the deformation of the deformable diaphragm 12. Conversely, when the electromechanical microsystem 1 acts as a sensor, the deforming of the diaphragm 12 exerts an external pressure change on the deformable medium 14 which causes a movement of the moving part 111, 111a, 111b of one of the electromechanical transducers 11, 11a, 11b.

As shown in FIG. 1A, the electromechanical microsystem 1 is such that the free area 121 of the deformable diaphragm 12 is configured to cooperate with an external member 2. In this way, the deformation of the free area 121 causes, or is caused by, a movement of the external member 2. It is thus through the free area 121 of the deformable diaphragm 12 that the microsystem moves the external member 2 or senses a movement of the external member 2. Thus, when the microsystem acts as an actuator, the activation of one of the electromechanical transducers 11, 11a, 11b deforms the diaphragm 12 which moves the member 2. Conversely, when the microsystem acts as a sensor, if an external member 2 is pressed against the diaphragm 12 or the diaphragm 12 is pulled by an external member 2, the diaphragm 12 is deformed, which moves the moving part of each of the electromechanical transducers 11, 11a, 11b and then ultimately generates a signal that may depend on this movement.

More particularly, the cooperation between the free area 121 of the deformable diaphragm 12 and the external member 2 may be achieved via a finger, also referred to as a pin 122, which is attached to the free area 121. The terms “finger” and “pin” may be interchanged. The term “pin” is not limited to parts with a constant cross-section, let alone cylindrical parts.

As shown in FIG. 1A, the pin 122 may be more particularly attached to the centre of the free area 121 of the deformable diaphragm 12, or more generally symmetrically about the extension of the free area 121 of the deformable diaphragm 12. In this way, the pin 122 is moved, through the elastic deformation of the free area 121, in a direction that is controlled and substantially vertical or albeit only slightly tilted with respect to the vertical, during its movements. The lateral movement of the pin 122 is thus advantageously limited.

Additionally or alternatively, the external member 2 may be structured to include a guide through which the external member 2 cooperates with the pin 122. This guide can also help to prevent the pin 122 from tilting when it moves. It will be seen later that the limitations thus achieved in terms of lateral deflection of the pin 122 may be further enhanced by the provision of at least one lateral stop 15 extending from a part of the wall 131 located outside the free area 121 of the deformable diaphragm 12.

In a non-limiting way, the pin 122 being bonded to or magnetized to the external member 2 may allow the pin 122 and the external member 2 to be made integral with each other. The energy with which the pin 122 adheres to the free area 121 of the deformable diaphragm 12 is preferably greater than that with which the pin 122 adheres to the outer member 2. The energy with which the pin 122 adheres to the free area 121 can be a result of ordinary technological steps in the field of microelectronics. Since this adhesion energy can thus be estimated or measured, it is easy to obtain by bonding, for example using an ad hoc resin or through magnetisation, for example, adhesion that is of lower energy than the energy with which the pin 122 adheres to the deformable diaphragm 12. It is thus understood that the connection between the pin 122 and the external member 2 can thus be largely adjusted in terms of holding force. This modularity may make it possible, in particular, to make the connection between the pin 122 and the external member 2 removable, for example to allow the same electromechanical microsystem 1, according to the invention, to be arranged successively with several external members 2 with each of which it would be connected and then disconnected.

As shown in FIG. 1A, each electromechanical transducer 11, 11a, 11b may form a part of the first wall 131 of the cavity 13. The electromechanical transducers 11, 11a and 11b and the deformable diaphragm 12 are thus positioned on the same side of the cavity 13. Structures with this feature are advantageously non-penetrating, as mentioned above.

In this non-limiting example, the diaphragm 12 has an inner face 12i configured to be in contact with the deformable medium 14 and an outer face 12e. The inner face 12i forms part of the first wall 131 of the cavity 13. In order to easily ensure the sealing of the cavity 13, the inner face 12i of the deformable diaphragm 12 forms the entire first wall 131 of the cavity 13. Each electromechanical transducer 11, 11a, 11b, more specifically the moving part 111, 111a, 111b thereof, has an inner face 11i facing, and preferably in contact with, the outer face 12e of the diaphragm 12. Each electromechanical transducer 11a, 11b also has an outer face 11e, opposite the inner face 11i, and facing the outside of the electromechanical microsystem 1. In order to easily ensure the hermetic sealing of the cavity 13, the inner face 11i of each electromechanical transducer 11, 11a, 11b is preferably entirely in contact with the outer face 12e of the diaphragm 12. One or more intermediate layers may be provided between the outer face 12e of the diaphragm 12 and the inner face 11i of each transducer 11, 11a, 11b. The electromechanical microsystem 1 is configured such that the movement of the moving part 111, 111a, 111b of each electromechanical transducer 11, 11a, 11b causes a deformation of the diaphragm 12 and thus of the first wall 131 which encloses the medium 14.

Note that in FIG. 1A:
each electromechanical transducer 11, 11a, 11b extends over the deformable diaphragm 12, with the electromechanical transducer 11 defining the free area 121 of the deformable diaphragm 12, and
the deformable diaphragm 12 separates each electromechanical transducer 11, 11a, 11b, preferably over their entire extension, from the deformable medium 14.

In addition, each electromechanical transducer 11, 11a and 11b may advantageously be integral with the deformable diaphragm 12. In particular, as the electromechanical transducer 11a and 11b do not define the free area 121 of the deformable diaphragm 12, they can advantageously be integral with the deformable diaphragm 12 over an area 123ab located outside the free area 121, and more particularly over an area 123ab distant from the free area 121, so that any movement of the moving part 111a, 111b of each of these transducers 11a, 11b causes, in particular in this area 123ab, the deformable diaphragm 12 to be stretched or relaxed. Thus, in the example shown in FIG. 1A, when the first transducer 11a is loaded to move upwardly (as shown by the dashed arrow extending from the moving part 111a of the transducer 11a), a decrease in the external pressure exerted on the deformable medium 14 is observed, which causes the deformable diaphragm 12 to be deformed downwardly, i.e., towards the centre of the cavity 13.

Still, in the example shown in FIG. 1A, when the second transducer 11b is loaded to move downwards (as shown by the dashed arrow extending from the moving part 111b of the electromechanical transducer 11), an increase in the external pressure exerted on the deformable medium 14 is observed, which causes the deformable diaphragm 12 to stretch upwards, i.e., away from the centre of the cavity 13. It should be noted here that this connection between the second transducer 11b and the deformable diaphragm 12 is only preferential for the shown microsystem, insofar as the moving part 111b of the second transducer 11b is intended to press against the deformable diaphragm 12 when the second transducer 11b is loaded and/or insofar as the deformable diaphragm 12 has a natural tendency to remain in contact with the moving part 111b of the second transducer 11b when the latter is not pressing against the deformable diaphragm 12.

According to the example shown in FIG. 1A, the third transducer 11 is configured to move downwards, i.e. towards the centre of the cavity 13, when loaded. This is particularly advantageous as it significantly simplifies the process of manufacturing the microsystem 1, in particular relative to a microsystem that would include a third transducer 11 configured to move upwards, i.e. away from the centre of the cavity 13. Although significantly more complex, however, the manufacturing of such a microsystem 1 is feasible, and the scope of the claims below does not necessarily exclude such a microsystem.

It should be noted, that in its equilibrium position, the moving part 111, 111a, 111b of each electromechanical transducer 11, 11a, 11b, and more generally one, or even each, transducer, cannot be flat, but may instead exhibit a deflection, known as the equilibrium deflection, which does not detract in any way, in terms of amplitude, from the movement or deflection capability of the electrically supplied transducer 11, 11a, 11b.

With reference to FIGS. 1A and 1B, a cover 18 may be provided which is configured, and which is more particularly sufficiently rigid, to hold:
the diaphragm 12 at least around the area 123 over which the third electromechanical transducer 11 extends and/or the area 123ab over which the first and second transducers 11a and 11b extend, the diaphragm 12 thus is partly located between the cover 18 and the deformable medium 14, and
the non-moving part of the third electromechanical transducer 11 and the non-moving part of the second electromechanical transducer 11b over which it extends.

The cover 18 extends in the xy-plane, for example. It has at least one opening that defines the area in which the moving part 111 of the third electromechanical transducer 11 extends and at least one opening in which the moving parts of the first and second electromechanical transducers 11a and 11b extend. In the area around the free area 121 of the deformable diaphragm 12, the cover 18 not only has the above-mentioned holding role, but may also act as lateral stops 15 (see below).

As shown in FIG. 1A, at least one spacer 306 may be provided which essentially has the role of contributing with the cover 18 to holding the moving part 111 of the third electromechanical transducer 11 and the non-moving part of the second transducer 11b. Indeed, the said at least one spacer 306 shown in FIG. 1A extends at least in line with a part of the cover 18 which, on the left of the figure, covers the non-moving part of the third electromechanical transducer 11 and which, on the right of this figure, covers the non-moving part of the second electromechanical transducer 11b, each of these non-moving parts thus being pinched between the cover 18 and the spacer 306. The said at least one spacer 306 may form at least a part of the side wall 133 of the cavity 13. Note that it is also possible to provide a spacer at a part of the cover 18 which is centred relative to the extension of the cavity 13 in the (x,y) plane, and in particular at such a part of the cover 18 which also extends over the non-moving part of the second transducer 11b.

FIG. 1B shows the partial covering of the deformable diaphragm 12 by the third electromechanical transducer 11. The third electromechanical transducer 11 is shaped like a ring of radial extension noted R and defines a circular free area 121 of radius noted R_{ZL}. Note that the third electromechanical transducer 11 is not limited to an annular shape, but may take other shapes, and in particular an oblong or oval shape, a triangular shape, a rectangular shape, etc. defining a corresponding plurality of shapes of the free area 121 of the deformable diaphragm 12. This illustration applies in particular to a local structure with a rotational or revolutionary symmetry.

In particular, when the partial overlap of the deformable diaphragm 12 by the third electromechanical transducer 11 is as shown in FIG. 1B and the third electromechanical transducer 11 is a piezoelectric transducer comprising a PZT-based piezoelectric material, it is advantageous for the moving part 111 of the third transducer 11 to have a surface area at least 2 times, or even 5 times, or even 10 times, or even 20 times, larger than the surface area of the free area 121 of the deformable diaphragm 12. The deformable diaphragm 12 is therefore configured such that its free area 121 is capable of being deformed with an amplitude of at least 50 μm, or about 100 μm, or even several hundred microns.

In general, the deformable diaphragm 12 is preferably configured such that its free area 121 is capable of being deformed with an amplitude of less than 1 mm.

The deformation amplitude of the free area 121 is measured along a direction perpendicular to the plane in which the outer face 12e of the diaphragm 12 at rest mainly extends.

Also when the partial overlap of the deformable diaphragm 12 by the electromechanical transducer 11 is as shown in FIG. 1B and the third electromechanical transducer 11 is a piezoelectric transducer comprising a PZT-based piezoelectric material, the radius RZL of the free area 121 of the deformable diaphragm 12 may be substantially equal to 100 μm and the radial extension R of the third electromechanical transducer 11 may be substantially equal to 350 μm. The references R and RZL are shown in FIG. 1B.

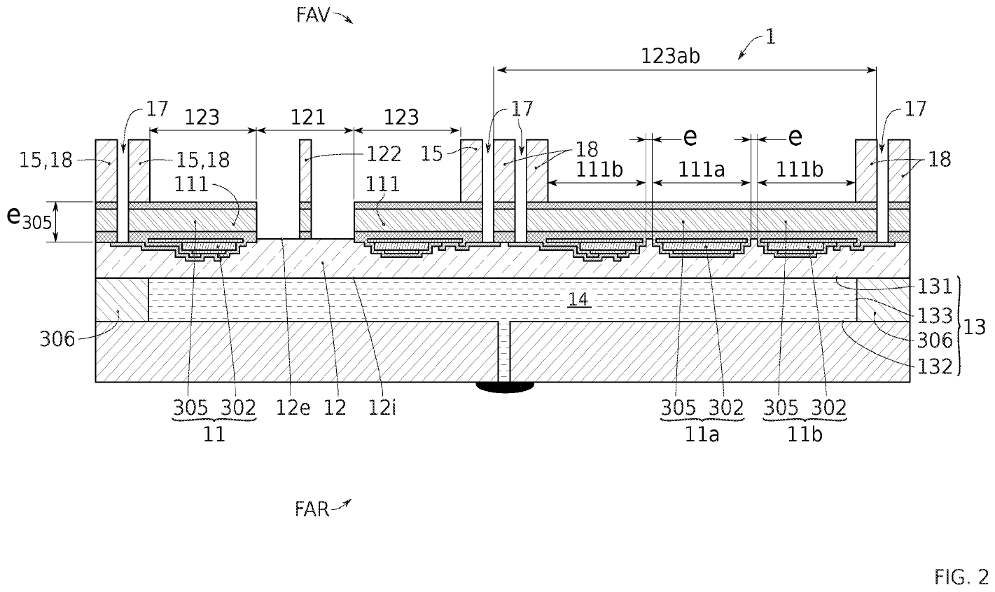

Still when the partial overlap of the deformable diaphragm 12 by the third electromechanical transducer 11 is as shown in FIG. 1B and that the third electromechanical transducer 11 is a piezoelectric transducer including a PZT-based piezoelectric material, but with reference to FIG. 2 discussed in more detail below, the third electromechanical transducer 11 more particularly includes an element forming a beam 305 and a PZT-based piezoelectric element 302, with the latter being configured to cause deflection of the beam 305. The thickness of the piezoelectric element 302 may be substantially equal to 0.5 μm and the thickness of the beam 305 is, for example, between a few microns and several tens of microns, for example, 5 μm. In such a configuration, the moving part 111 of the third electromechanical transducer 11 can be moved or deflected with an amplitude substantially equal to 15 μm when subjected to an electrical voltage of a few tens of volts.

FIG. 1B also shows the partial covering of the deformable diaphragm 12 by the first and second electromechanical transducers 11a and 11b according to the first embodiment of the invention. The first transducer 11a is shaped like a disc with a radius noted R1. The second transducer 11b is shaped like a ring extending around the disc 11a over a radial extension R2. The disc 11a and the ring 11b are preferably concentric. The disc 11a and the ring 11b may be, as shown, adjacent to each other, the ring 11b then having a radial extension equal to R2. Alternatively, the disc 11a and the ring 11b may be spaced apart, with the ring 11b then having a radial extension of less than R2.

The radius R1 of the disc 11a is, for example, between a few tens and a few hundreds of microns, and is typically equal to 200 microns. The radial extension R2 of the area extending around the disc 11a is, for example, between a few tens and a few hundreds of microns, and is typically equal to 100 microns. When the first and second transducers 11a and 11b are spaced apart, the radial extension of this spacing is, for example, between 1 and 10 microns, and is typically equal to 5 microns. It is understood here that as each of the first and second electromechanical transducers 11a and 11b has its own moving part 111a, 111b, the moving part of one of the two transducers 11a and 11b can be loaded independently from, and in particular alternately to, the moving part of the other of the two transducers 11a and 11b.

In a configuration in which the first and second electromechanical transducers 11a and 11b are contained within the boundaries of a circular area of given radius known as the “total radius” and noted Rₜₒₜ, with the said circular area comprising two parts, a first disc-shaped part centred on the said circular area and a second ring-shaped part extending around the first part, the said at least one first electromechanical transducer 11a may be contained within the first part of the circular area and the said at least one second electromechanical transducer 11b may be contained within the second part of the circular area. Then, if the first part of the circular area has a radius R_{2/3} substantially equal to two thirds of the total radius and if the second part of the circular area has an extension E_{1/3} substantially equal to one third of the total radius, the deformation of the moving part 111a of the first electromechanical transducer 11a then opposes, and more particularly in an opposite direction in the direction of the z-axis, the deformation of the moving part 111b of the second electromechanical transducer 11b. It is then possible, even when each of the two transducers 11a and 11b includes a PZT-based piezoelectric transducer, to alternately cause, depending on which of the two transducers 11a and 11b is loaded, a movement away from and towards the free area 121 of the diaphragm 12 with respect to at least one wall among the walls 132, 133 of the cavity 13. For example, the first electromechanical transducer 11a is configured to move upwards, i.e. away from the centre of the cavity 13, when loaded, and the second electromechanical transducer 11b is configured to move downwards, i.e. towards the centre of the cavity 13, when loaded.

In addition, it is advantageous for the radial extension R2 of the second transducer 11b to be about half the radius R1 of the first transducer 11a. In such a configuration, the moving part 111a of the first transducer 11a and the moving part 111b of the second transducer 11b can be moved or deflected with a substantially equal amplitude, when the transducers are alternately and substantially equally loaded.

Also when the partial overlap of the deformable diaphragm 12 by the two transducers 11a and 11b is as shown in FIG. 1B and the transducers 11a and 11b are piezoelectric transducers each including a PZT-based piezoelectric material, the radius R_{ZL} of the free area 121 of the deformable diaphragm 12 may be substantially equal to 100 μm for a radius R1+R2 of 300 μm and/or the radius R1 of the first electromechanical transducer 11a may be substantially equal to 200 μm for a radius R1+R2 of 300 μm. The references R_{ZL}, R, R1 and R2 are shown in FIG. 1B.

Each of the first and second electromechanical transducers 11a and 11b more particularly consist of a member comprising a beam 305 and a PZT-based piezoelectric element 302, the latter being configured to cause a deflection of the beam 305. The thickness of the piezoelectric element 302 may be substantially equal to 0.5 μm and the thickness of the beam 305 is, for example, between a few microns and several tens of microns, for example, 5 μm. In such a configuration, when R1 is equal to 200 microns and R2 is equal to 100 microns, the amplitude of movement of the moving parts 111a, 111b of the transducers 11a and 11b may reach a value equal to a few tens of microns, in particular when a voltage of a few tens of volts is applied across one or other of the transducers 11a and 11b.

It is immediately apparent from FIG. 1B that the free area 121 of the diaphragm 12 is spaced from, or is separated from, the area 123ab over which the first and second transducers 11a and 11b overlap the diaphragm 12. In other words, the free area 121 and the area 123ab do not overlap each other, nor are they adjacent to each other. A distance is therefore left between area 121 and area 123ab.

It is again immediately apparent from FIG. 1B that the free area 121 of the diaphragm 12 is off-centred with respect to the area 123ab over which the two transducers 11a and 11b cover the diaphragm 12. This feature is related to the fact that the first transducer 11a is disc-shaped, and is therefore solid.

Without tearing and/or significant wear, the electromechanical microsystem 1 allows for hydraulic amplification of the action and thus offers the ability to meet the requirements of many different applications requiring a large amount of travel. In this context, the electromechanical microsystem 1 shown in FIG. 1A can be defined as an actuator with a large upwards or downwards travel.

It is again apparent from FIG. 1B that the at least one lateral stop 15 may be shaped like a ring extending from the first cavity wall 131 and around the free area 121 of the diaphragm 12. Similar observations can be made on the basis of FIG. 1C.

FIG. 1C shows, according to a second embodiment of the invention, the partial covering of the deformable diaphragm 12 by four electromechanical transducers 11a, 11b, 11 c and 11d, each represented by their moving parts 111a, 111b, 111c and 111d. FIG. 1C is more particularly a top view of the electromechanical microsystem according to the second embodiment of the invention. The first electromechanical transducer 11a is shaped like a disc of radial extension R1; The second electromechanical transducer 11b is shaped like a ring extending around the disc 11a over a radial extension area R2; The third electromechanical transducer 11c is shaped like a ring extending around the disc 11a and the ring 11b over a radial extension area R3; And the fourth ring-shaped electromechanical transducer 11d extending around the ring 11b over a radial extension area R4.

The third and fourth transducers 11c and 11d are, in the example shown in FIG. 1C, alternative to the third transducer 11 as shown in FIG. 1B. According to a hybrid embodiment (not shown) between the first and second embodiments of the microsystem according to the invention, the transducers 11c and 11d may in addition to, rather than as an alternative to, the third transducer 11 as shown in FIG. 1B.

The transducers 11a, 11b, 11c and 11d according to the second embodiment of the invention are preferably concentric. Two radially successive electromechanical transducers 11a, 11b, 11c and 11d are either spaced apart or adjacent to each other. Their moving parts are, for example, separated from each other by a distance noted e in FIG. 1C. This distance can be compared to the one also noted e in FIG. 2 detailed below. However, in the latter Figure, the distance e is intended more to show that the piezoelectric elements 302 of adjacent transducers must not to touch each other in order to be electrically isolated from each other, than to show that the transducers can be spaced apart, even when they are arranged concentrically to each other.

In the embodiment shown in FIG. 1C, R1 is, for example, between 10 and 100 μm, R2 between 10 and 100 μm, R3 between 10 and 100 μm, and R4 between 10 and 100 μm. Typically, R1 is 100 microns, R2 is 50 microns, R3 is 50 microns and R4 is 50 microns. When the two electromechanical transducers radially successive between each other are spaced apart, the radial extension of this spacing is, for example, between 1 and 10 microns, and is typically equal to 10 microns.

The deformation of the moving parts 111a and 111c of the transducers 11a and 11c can advantageously oppose the deformation of the moving parts 111b and 111d of the transducers 11b and 11d. For this purpose, the transducers 11a and 11c may be contained within a disc of radius less than ⅔ of the total radial extension R1+R3+R2+R4 of the transducers.

Alternatively, the transducer 11a may be contained within a first circular area of radius less than two-thirds of the total radial extension R1+R3+R2+R4 of the transducers and the other three transducers 11b, 11c and 11d may extend beyond the first circular area over an annular radial extension area of less than one-third of the total radial extension R1+R3+R2+R4 of the transducers.

Another alternative involves considering that the three transducers 11a, 11b and 11c are located in the first circular area with a radius of less than two thirds of the total radial extension R1+R3+R2+R4 and that the fourth electromechanical transducer 11d is located in the annular area with a radial extension of less than one third of the total radial extension R1+R3+R2+R4 of the transducers.

As already discussed above with reference to the embodiment shown in FIG. 1B, it is then possible, even when each of the two transducers 11a, 11b, 11c and 11d includes a PZT-based piezoelectric transducer, to alternately cause, depending on which of the two transducers 11a, 11b, 11c and 11d is loaded, a movement away from and towards the free area 121 of the diaphragm 12 with respect to at least one wall among the walls 132, 133 of the cavity 13. For example, each of the first and third electromechanical transducers 11a and 11c is configured to move upwards, i.e. away from the centre of the cavity 13, when loaded, and each of the second and fourth transducers 11b and 11d is configured to move downwards, i.e. towards the centre of the cavity 13, when loaded.

It is understood that an additional advantage, with respect to the first embodiment schematically shown in FIGS. 1A and 1B, is that the embodiment shown in FIG. 1C may make it possible to obtain more mutually different distances when moving away from the free area 121 and/or more mutually different distances when moving towards the free area 121. The electromechanical microsystem 1 according to the second embodiment of the invention thus forms a step-by-step actuator, capable of deforming the free area 121 between at least four elevation and/or approach positions, in particular when each of the transducers 11a, 11b, 11c and 11d operates in a binary mode. According to this binary mode, the supply voltage of each of the transducers 11a, 11b, 11c and 11d may alternately vary between 0 V and 20 V.

In such a configuration, when the transducers 11a and 11c are contained within a disc of radius less than ⅔ of the total radial extension R1+R3+R2+R4 of the transducers:
the moving part 111a of the first transducer 11a can be moved or deflected with an amplitude of between a few microns and a few tens of microns when subjected to an electrical voltage of about ten volts; the moving parts 111a and 111c of the first and third transducers 11a and 11c can be jointly moved or deflected with a higher amplitude by both being subjected to the same voltage of about ten volts;
the moving part 111b of the second transducer 11b can be moved or deflected with an amplitude of between a few microns and a few tens of microns when subjected to an electrical voltage of about ten volts; and the moving parts 111b and 111d of the second and fourth transducers 11b and 11d can be jointly moved or deflected with a higher amplitude by both being subjected to the same voltage of about ten volts.

It is understood that the configuration shown in FIG. 1C makes it possible to achieve, by supplying the transducers with a voltage substantially equal to about ten volts, amplitudes of deformation of the free area 121 of the diaphragm 12 substantially equivalent to those potentially achieved by the first and second transducers 11a and 11b alone, supplied alternately with a much higher electrical voltage, and for example substantially equal to 50 V. Thus, further simplification of the electronics required to implement the microsystem 1 is achieved.

It should be noted here that the electromechanical microsystem 1 according to the second embodiment is not limited to the example shown comprising two additional transducers 11c and 11d (each having an annular shape) in relation to the first embodiment. More particularly, the second embodiment extends to a case comprising a single additional annular-shaped transducer and a case comprising more than two additional annular-shaped transducers.

A third embodiment is shown in FIG. 1D, which may be considered to be in all respects consistent with the second embodiment described above with reference to FIG. 1C, except that it has a plurality of free areas 121a, 121b, 121c, 121d, and 121e. Each of these may be smaller in area, or even up to five times smaller, than the area of a single free area 121 as shown in FIG. 1C. In another example, the surface area of each moving part or parts of the transducers shown in FIG. 1D is at least 5 times, and possibly 10 times, or even 20 times larger than the surface area of the free areas 121a, 121b, 121c, 121d, and 121e of the deformable diaphragm 12. They may also differ in size and/or shape. A distribution of the movement force of a single external member 2 arranged opposite such a plurality of free areas can thus be advantageously achieved. Alternatively or additionally, greater stability in the movement of the external member 2 arranged opposite such a plurality of free areas can thus be advantageously achieved, in particular when the extension of the external member is significant in relation to the surface area of a single free area 121 as shown in FIG. 1C. Alternatively, an external member 2 can be arranged opposite a single free area of the plurality or some free areas of the plurality; a joint movement of several external members 2 can thus be achieved.

A fourth embodiment is shown in FIG. 1E, which may be considered to be in all respects consistent with the first embodiment described above with reference to FIGS. 1A and 1B, except that the fourth embodiment as shown in FIG. 1E does not include a transducer 11 defining the free area 121 of the diaphragm 12, but includes, in place of this transducer 11, three additional sets of first and second transducers 11a and 11b. However, the fourth embodiment is not limited to the example shown in FIG. 1E; in particular, consideration to given to adding one or two or even more sets to the three shown.

It is understood from the example shown in FIG. 1E that the amplitude of deformation of the free area of the diaphragm can be increased fourfold relative to a case comprising only one set of first and second transducers 11a and 11b; the free area 121 may therefore have a significantly increased surface area for the same deformation amplitude relative to the first embodiment. Alternatively, it is understood from the example shown in FIG. 1E, that the supply voltage to each transducer may be decreased from a nominal supply voltage, to achieve an amplitude of deformation of the free region of the diaphragm that is comparable to amplitude potentially achieved by supplying a single set of first and second transducers 11a and 11b at the nominal voltage.

It should be noted that in FIGS. 1D and 1E, the cover 18 and the said at least one lateral stop are referred to, which are consistent with the description given above, in particular with reference to FIGS. 1A and 1B.

It should be noted that the scope of the appended claims does not preclude a microsystem combining different sets of the aforementioned transducers 11, 11a, 11b, 11c and 11d. Thus, and by way of non-limiting examples, the embodiment shown in FIG. 1D could include, in addition to or as an alternative to the transducers 11, 11a, 11b, 11c and 11d, at least one set of first and second transducers 11a and 11b as shown in FIG. 1B; the embodiment shown in FIG. 1E could include a set of transducers 11a, 11b, 11c and 11d as shown in FIG. 1D in addition to or as an alternative to at least one set of first and second transducers 11a and 11b as shown in FIG. 1E.

It should be noted that, regardless of which of the embodiments of the electromechanical microsystem according to the invention described above is used, each electromechanical transducer 11, 11a, 11b, 11c, 11d is not limited to an annular or disc shape, respectively, but may take on other shapes, and in particular a hollow or solid oblong, oval, triangular, rectangular, etc. shape, depending on the transducer considered. The illustrations in FIGS. 1B to 1E apply in particular to a structure of electromechanical transducers with a rotational or revolutionary symmetry. However, the invention is not limited to such structures of electromechanical transducers with a rotational or revolutionary symmetry.

In particular, when the partial overlap of the deformable diaphragm 12 by the electromechanical transducers is as shown in FIGS. 1C to 1E and each electromechanical transducer is a piezoelectric transducer comprising a PZT-based piezoelectric material, it is advantageous for the moving part 111, 111a, 111b, 111c and 111d of each of the first and second electromechanical transducers 11, 11a, 11b, 11c and 11d to have a surface area at least 2 times larger than the surface area of the free area 121 of the deformable diaphragm 12. The deformable diaphragm 12 is therefore configured such that its free area 121 is capable of being deformed with an amplitude of at least 50 μm, or about 100 μm, or even several hundred microns. In general, the deformable diaphragm 12 is configured such that its free area 121 is capable of being deformed with an amplitude of less than 1 mm. This deformation is measured along a direction perpendicular to the plane in which the outer face 12e of the diaphragm 12 at rest mainly extends. Without tearing and/or significant wear, the electromechanical microsystem 1 allows for hydraulic amplification of the action and thus offers the ability to meet the requirements of many different applications requiring a large amount of travel. In this context, the electromechanical microsystem 1 according to each of the two embodiments described above can be defined as an actuator with a large upwards and downwards travel.

As already mentioned above, each electromechanical transducer 11, 11a, 11b, 11c, 11d more particularly consists of an element comprising a beam 305 and a PZT-based piezoelectric element 302, the latter being configured to cause a deflection of the beam 305. The thickness of the piezoelectric element 302 may be substantially equal to 0.5 μm and the thickness of the beam 305 is preferably between a few microns and several tens of microns, for example, substantially equal to 5 μm.

However, the invention is not limited to the various specific values given above, which can be largely adjusted, depending on the intended application, in particular to obtain a compromise between stretch factor and expected deformation amplitude of the free area 121 of the deformable diaphragm 12.

Note that, in particular when one of the electromechanical transducers is a piezoelectric transducer, it can advantageously be a transducer with a vibratory operation. Its resonant frequency is then preferably lower than 100 kHz, and even more preferably lower than 1 kHz. The vibratory dynamics thus obtained can make it possible to achieve greater deflections than in static operation, in particular by using the related resonance phenomenon, or to reduce the consumption of the electromechanical microsystem for a given deflection.

As already mentioned above, the electromechanical microsystem 1 may further comprise one or more lateral stops 15 supported by the wall 131 of the cavity 13. Each side stop 15 extends more particularly away from the cavity 13.

Relative to the side stops 15, the pin 122 may extend beyond or within the cavity 13.

The lateral stops 15 may also be configured to allow the external member 2 to be guided and self-positioned on the electromechanical microsystem 1. It further contributes to limiting, or even eliminating, the risk of the deformable diaphragm 12 being torn off when the external member 2 is transferred to the electromechanical microsystem 1. It should be noted here that, depending on the extension of the external member 2, the side stops 15 can also act as an upper stop limiting the movement of the external member 2 towards the electromechanical microsystem 1. When the free area is configured to cooperate with at least one external member so that its deformation causes, or is caused by, a movement of the external member, this feature may also cause the pin 122 and the external member 2 to disengage from each other by pulling the pin 122 to a lower position than the one that the external member 2 may have reached due to the fact that the latter abuts against the top of the lateral stops 15. More specifically, the side stops 15 then have a stop surface area configured to stop the movement of the member 12. The electromechanical microsystem 1 is configured so that, when the movement of the member 12 is stopped, in a given direction, by the side stops 15, the pin 122 can continue its movement, in the same direction. The pin 122 thus disengages from the member 12.

As shown in FIG. 1A, the electromechanical microsystem 1 may further comprise one or more so-called bottom stops 16 supported by the wall 132 of the cavity 13 that is opposite the wall 131 formed at least in part by the deformable diaphragm 12 and extending into the cavity 13 toward the free area 121 of the deformable diaphragm 12. This bottom stop 16 preferably has a shape and dimensions configured to limit the deformation of the free area 121 of the deformable diaphragm 12 so as to protect the deformable diaphragm 12, and more particularly its free area 121, from any possibility of being torn off, in particular when the external member 2 is transferred to the electromechanical microsystem 1. Alternatively or cumulatively, the bottom stop 16 is shaped to limit the contact area between the diaphragm 12 and the wall 132 of the cavity 13 opposite the free area 121 of the deformable diaphragm 12. This prevents the diaphragm 12 from adhering to this wall 132.

A more specific embodiment of the invention than the one described above with reference to FIGS. 1A and 1B is shown in FIG. 2, in which the same references as in FIGS. 1A and 1B refer to the same objects.

First, it is observed that each electromechanical transducer 11, 11a, 11b shown includes a beam 305 and a piezoelectric material 302 configured to deform the beam 305 when it is supplied with electrical power. More particularly, the first and second transducers 11a and 11b share a common beam 305, with their piezoelectric elements 302 being arranged opposite different areas of the beam 305.

It is also noted that the piezoelectric elements 302 of the transducers 11, 11a and 11b are all located on the same side of the beam 305 or equivalently of the neutral fibre of these transducers. As mentioned above, this embodiment, which is in principle consistent with that shown in FIG. 1A, is advantageously simple in construction relative to the construction of a microsystem in which the piezoelectric element 302 of the third transducer 11 would be on the other side of the beam 305 from the piezoelectric elements 302 of the first and second transducers 11a and 11b.

It is understood that the piezoelectric element 302 of the first transducer 11a is designed to primarily deform the beam 305 in a central area of the area 123ab into which the piezoelectric elements of the first and second transducers 11a and 11b extend, whereas the piezoelectric element 302 of the second transducer 11b is designed to primarily deform the beam 305 in an area peripheral to the said central area.

It is further apparent from FIG. 2 that the moving part 111, 111a, 111b of each electromechanical transducer 11, 11a, 11b may be substantially defined by the extension of the piezoelectric element 302 relative to the extension of the beam 305.

FIG. 2 also shows access openings for an electrical connection of the electrodes. These openings in these examples form vias 17. In this example, the vias 17 extend through the entire thickness of the beam 305. The thickness e₃₀₅ of the beam 305 is measured along a direction perpendicular to the plane in which the faces 12e and 12i of the diaphragm 12 mainly extend. The thickness e₃₀₅ is referenced in FIG. 2.

FIG. 2 shows more particularly, than do FIGS. 1A and 1B, the first embodiment of the invention already discussed above. In particular, FIG. 2 shows the first embodiment of the invention as obtained by the deposition and etching steps that may be characterised as ordinary in the microelectronics field (and this may also be the case for each of the other embodiments of the invention). More particularly, the electromechanical microsystem 1 according to the first embodiment shown in FIG. 2 was obtained through a manufacturing process including at least:
a step involved in forming what is to be at least a portion of each electromechanical transducer 11, 11a and 11b on a substrate, and then
a step involving the deposition of the deformable diaphragm 12, and then
a step involving the forming of an open cavity 13 on the deformable diaphragm 12, and then
a step involving the filling with the deformable medium and the closing of the cavity 13, and
a step involving the etching of the substrate to form the front of the electromechanical microsystem 1 shown in FIG. 2.

It should also be noted that each cover 18 and each side stop 15 discussed above are also formed by carrying out the technological steps, the result of which is shown in FIG. 2. Each cover 18 and each side stop 15 is in the form of a structured stack extending directly from the deformable diaphragm 12 away from the cavity 13 with successively the material of one insulating layer, the material forming the beam 305 and the material of another insulating layer.

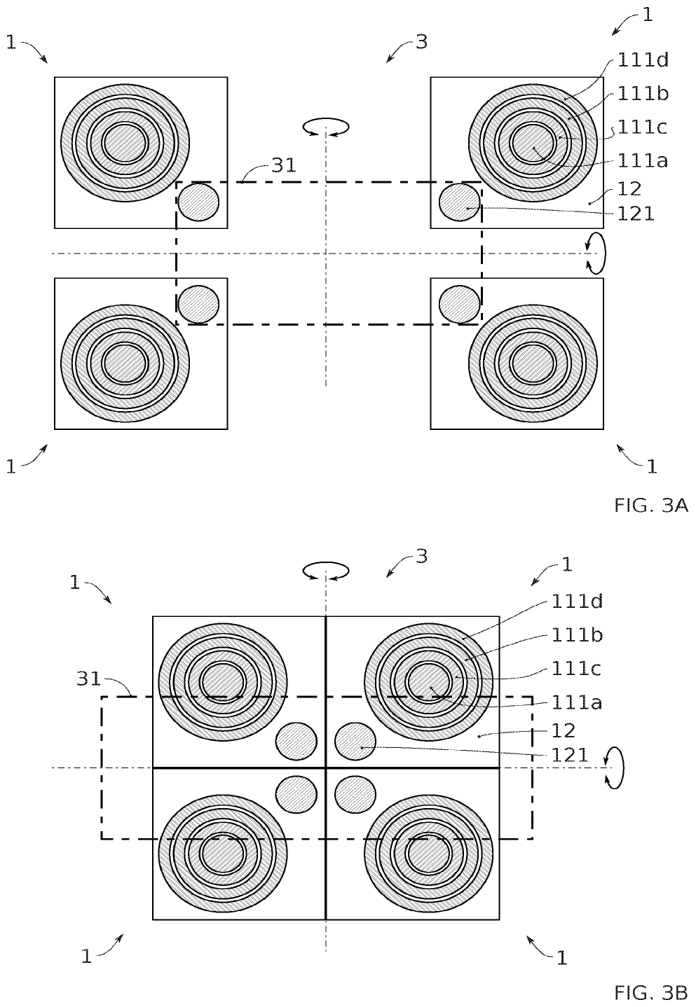

Another aspect of the invention relates to an opto-electromechanical system 3 as shown in FIGS. 3A, 3B, 4A and 4B. This may be an opto-electromechanical microsystem 3. Each of the opto-electromechanical microsystems 3 shown in these figures includes at least one electromechanical microsystem 1 as described above and at least one optical microsystem 31. The said at least one electromechanical microsystem 1 is preferably mounted on a support 32 of the opto-electromechanical microsystem 3. The said at least one optical microsystem 31 may comprise a silicon-based micromirror, the surface of which may be topped with at least one mirror. It may be mounted directly on the said at least one electromechanical microsystem 1 or mounted thereon via a frame 33. It may have dimensions substantially equal to 2 mm×5 mm and/or, at most, a thickness of about 700 μm. The opto-electromechanical microsystems 3 as shown each comprise four electromechanical microsystems 1 each having a free area 121 arranged opposite a part of the same optical microsystem 31, this part being specific and preferably a corner of the said optical microsystem 31 or of its centre. This results in an opto-electro-mechanical microsystem 3 with a large capacity to adapt its optical orientation.

It should also be noted that, because of the possibility offered by each electromechanical microsystem 1, according to the invention, of acting on the optical microsystem 31 by moving it upwards and downwards in step mode, the achievable angles of tilt of the optical microsystem 31 are thus advantageously increased by an amplitude, relative to electromechanical microsystems that do not allow operation in step mode. Better control at each instant and better reproducibility of the tilt angle of the optical microsystem 31 are achieved since each potentially achieved tilt angle belongs to a predetermined set of tilt angles, due to the potentially binary operation of the transducers used.

It should be further noted that it may be advantageous, in the context of the incorporation of an electromechanical microsystem 1 according to the first aspect of the invention with an opto-electromechanical microsystem 3 according to the second aspect of the invention, for the electromechanical microsystem 1 used to be chosen from the ones described above (and envisaged below) which do not include a third transducer 11. Indeed, due to the decentring of the free area 121 of the deformable diaphragm 12 relative to the area 123ab over which the first and second electromechanical transducers 11a and 11b extend, it is then possible to arrange the free areas 121 of the four electromechanical microsystems 1 as close as possible to the corners or centre of the optical microsystem 31, and in particular potentially closer than would be possible with electromechanical microsystems in each of which the free area 121 of the deformable diaphragm 12 would be centred on the area 123 of a third electromechanical transducer 11 as schematically illustrated in FIG. 1A. The achievable tilt angles of the optical microsystem 31 are thus advantageously of an increased amplitude.

The invention is not limited to the previously described embodiments and extends to all embodiments covered by the claims.

In particular, the embodiments described above mostly include at least three electromechanical transducers. However, the microsystem 1 according to the first aspect of the invention may only include two electromechanical transducers.

A first schematic representation of an example of such a microsystem 1 is obtained by considering, in FIG. 1A, that the first and second transducers form only one and the same transducer configured to move, when loaded, in the same direction as the transducer 11 (the latter being able to be configured to move in either of the two directions).

A second schematic representation of an example of a microsystem 1 according to the first aspect of the invention comprising two electromechanical transducers is obtained by considering, in FIG. 1A, that only the two transducers 11a and 11b are provided, and that the transducer 11 is removed. The remaining two transducers 11a and 11b must then be configured to move in the same direction. Either they are not PZT-based, and can move in either direction; or they are PZT-based, and, with the electromechanical transducers 11a and 11b not contained within the boundaries of a circular area of given radius known as the “total radius” and noted Rtot, with the said circular area comprising two parts, a first disc-shaped part centred on the said circular area and a second ring-shaped part extending around the first part, the first electromechanical transducer 11a is not entirely contained within the first part of the circular area, but extends beyond it, or the second electromechanical transducer 11b is not entirely contained within the second part of the circular area, but extends beyond it into the first part.

A third schematic representation of an example of a microsystem 1 according to the first aspect of the invention comprising two electromechanical transducers is provided considering, in FIG. 1E, that only two transducers 11a each having a moving part 111a are provided, with the other two transducers 11a and the four transducers 11b being removed and the remaining two transducers 11a being configured to move in the same direction when loaded (the latter may be configured to move in either direction).

In addition, other applications than those described above are possible. For example, the electromechanical microsystem 1 can be arranged in a micropump, or even in a micropump array system, or in a haptic system.

1. An electromechanical microsystem comprising:
at least two electromechanical transducers each comprising a part moving between an equilibrium, non-loaded position and an out-of-equilibrium, loaded position,
at least one deformable diaphragm,
a deformable cavity bounded by walls, at least part of the deformable diaphragm forming at least part of a first wall of the walls of the cavity, the cavity hermetically containing a deformable medium maintaining a substantially constant volume under an action of a change in external pressure exerted on the deformable medium through one of the walls of the cavity, wherein
the moving part of each electromechanical transducer is configured to move as a function of the change in external pressure, or conversely to move causing a change in external pressure, and at least one part of the deformable diaphragm is provided with at least one area free to deform, depending on the change in external pressure,
the moving parts of the at least two electromechanical transducers are configured so that:
their loading or an increase in external pressure causes their movement towards the outside of the cavity, or
their loading or a decrease in external pressure causes their movement towards the inside of the cavity,
the at least one free area cooperates with at least one external member so that its deformation causes, or is caused by, a movement of the external member, and
the free area of the deformable diaphragm cooperates with the external member via a pin attached to the free area and in contact with the said free area.

2. The electromechanical microsystem according to claim 1, including at least three electromechanical transducers each comprising a part moving between an equilibrium, non-loaded position and an out-of-equilibrium, loaded position,
the moving part of each electromechanical transducer being configured to move as a function of the said external pressure change or conversely to move causing an external pressure change,
wherein:
the moving part of a first electromechanical transducer is configured so that its loading or an increase in external pressure causes its movement towards the outside of the cavity,
the moving part of a second electromechanical transducer is configured so that its loading or a decrease in external pressure causes its movement towards the inside of the cavity, and
the moving part of a third electromechanical transducer is configured such that its loading or an external pressure increase causes its movement towards the outside and/or inside of the cavity.

3. The electromechanical microsystem according to claim 1, wherein the loading of at least one of the at least two electromechanical transducers is such that its moving part moves from its equilibrium position to a given non-equilibrium position.

4. The electromechanical microsystem according to claim 1, wherein two of the said at least two electromechanical transducers extend, on at least one of the walls of the cavity, at a distance from the free area of the deformable diaphragm.

5. The electromechanical microsystem according to claim 1, wherein a first one of the at least two electromechanical transducers is shaped like a disc of radius R1 and a second one of the at least two electromechanical transducers is shaped like a ring extending in a radial extension R2 around the disc formed by the first electromechanical transducer.

6. The electromechanical microsystem according to claim 5, wherein the radial extension of the ring formed by the second electromechanical transducer is substantially twice as small as the radius R1 of the disc formed by the first electromechanical transducer.

7. The electromechanical microsystem according to claim 6, comprising a third electromechanical transducer, and with the first and second electromechanical transducers is contained within boundaries of a circular area of given radius known as a total radius and noted Rₜₒₜ, the circular area comprising two parts, a first disc-shaped part centred on the said circular area and a second ring-shaped part extending around the first part,
wherein the at least one first electromechanical transducer is contained within the first part of the circular area and the said at least one second electromechanical transducer is contained within the second part of the circular area, with the first part of the circular area having a radius substantially equal to two thirds of the total radius and the second part of the circular area having an extension substantially equal to one third of the total radius.

8. The electromechanical microsystem according to claim 2, wherein the third electromechanical transducer extends over at least one of the walls of the cavity and over an annular area around the free area of the deformable diaphragm.

9. The electromechanical microsystem according to claim 7, comprising, as an alternative to or in addition to the third electromechanical transducer, at least one other ring-shaped electromechanical transducer extending around the first disc-shaped electromechanical transducer or around the second ring-shaped electromechanical transducer, the moving part of the at least one other electromechanical transducer is deformed when loaded, in directions opposite to each other, according to whether it is contained:
within a first part of a circular area within boundaries of which are contained the first and second electromechanical transducers and the at least one other electromechanical transducer, this first part having a radius substantially equal to two thirds of the radius of the said circular area, or
within a second part of the circular area, this second part having an extension substantially equal to one third of the radius of the circular area.

10. The electromechanical microsystem according to claim 9, comprising, as an alternative to or addition to the third electromechanical transducer and/or to the at least one other electromechanical transducer, at least two other electromechanical transducers extending, on at least one of the walls of the cavity, at a distance from the free area of the deformable diaphragm and from the first and second electromechanical transducers and being arranged neither around the free area of the deformable diaphragm, nor around the first and second electromechanical transducers, wherein a first of the at least two other electromechanical transducers is disc-shaped and a second of the at least two other electromechanical transducers is shaped like a ring extending around the disc formed by the first of the at least two other electromechanical transducers.

11. The electromechanical microsystem according to claim 1, wherein the deformable diaphragm has a plurality of free regions, which may have different shapes and/or dimensions from one another.

12. The electromechanical microsystem according to claim 1, wherein the pin is attached to a centre of the free area of the deformable diaphragm.

13. The electromechanical microsystem according to claim 1, wherein at least a part of each electromechanical transducer forms a part of the first wall of the cavity.

14. The electromechanical microsystem according to claim 2, wherein the moving part of at least one of the said at least two electromechanical transducers is integral with an area of the deformable diaphragm over which it extends, so that a movement of the moving part causes a corresponding movement of the area of the deformable diaphragm.

15. The electromechanical microsystem according to claim 1, wherein the deformable diaphragm is configured so that each free area is capable of being deformed with an amplitude of at least 50 μm in a direction perpendicular to a plane in which the deformable diaphragm primarily extends when at rest.

16. The electromechanical microsystem according to claim 1, wherein, the moving part of at least one of the at least two electromechanical transducers has a surface area at least twice as large as a surface area of the at least one free area of the deformable diaphragm.

17. The electromechanical microsystem according to claim 1, wherein at least one of the said at least two electromechanical transducers is a piezoelectric transducer.

18. The electromechanical microsystem according to claim 1, wherein at least one of the at least two electromechanical transducers is a statically-operating transducer.

19. The electromechanical microsystem according to claim 1, wherein at least one of the at least two electromechanical transducers is a vibratory-operating transducer with at least one resonant frequency, the at least one resonant frequency being less than 100 kHz.

20. The electromechanical microsystem according to claim 1, wherein the deformable medium hermetically contained in the cavity comprises at least one fluid.

21. An opto-electromechanical system including at least one electromechanical microsystem according to claim 1 and at least one optical microsystem.

22. The opto-electromechanical system according to claim 21, wherein the at least one optical microsystem includes at least one mirror, the opto-electromechanical system being configured such that the movement of the moving part of each electromechanical transducers causes a movement of the at least one mirror.

23. The opto-electromechanical system according to claim 21, comprising a plurality of the electromechanical microsystems and each at least having a free area arranged opposite a part of the same optical microsystem.

24. A process of manufacturing an electromechanical microsystem according to claim 1, comprising:
forming, on a substrate, at least a portion of each of the said at least two electromechanical transducers, and then
depositing the deformable diaphragm, and then
forming at least one open cavity on the deformable diaphragm, and then
filling with the deformable medium and closing the cavity, and
etching the substrate to form a front face of the electromechanical microsystem.
